(19) United States
(12) Patent Application Publication
(10) Pub. No.: US 2017/0263187 A1
(43) Pub. Date: Sep. 14, 2017

(54) ORGANIC LIGHT-EMITTING PIXEL DRIVING CIRCUIT, DRIVING METHOD THEREOF, AND ORGANIC LIGHT-EMITTING DISPLAY PANEL

(71) Applicant: Shanghai Tianma AM-OLED Co., Ltd., Shanghai (CN)

(72) Inventors: Renyuan ZHU, Shanghai (CN); Yue LI, Shanghai (CN); Tong WU, Shanghai (CN); Dongxu XIANG, Shanghai (CN); Zeyuan CHEN, Shanghai (CN)

(21) Appl. No.: 15/599,704

(22) Filed: May 19, 2017

(30) Foreign Application Priority Data
Jan. 10, 2017 (CN) 201710015814.6

(51) Int. Cl. G09G 3/3258; H01L 27/32

(52) U.S. Cl. CPC G09G 3/3258; H01L 27/3276; G09G 2300/0809

(57) ABSTRACT

An organic light-emitting pixel driving circuit, a driving method thereof, and an organic light-emitting display panel are provided. The organic light-emitting pixel driving circuit comprises a light-emitting element, a driving transistor that drives the light-emitting element, a first to a fifth transistors, and a capacitor. The first transistor is configured to transmit an initialization voltage to the light-emitting element. The second transistor is configured to transmit the initialization voltage to the driving transistor and compensate a threshold voltage of the driving transistor. The third transistor is configured to transmit a data signal voltage to the driving transistor. The fourth transistor is configured to transmit a first power supply voltage signal to the driving transistor. The fifth transistor is configured to control an electric connection between the driving transistor and an anode of the light-emitting element. The capacitor is configured to store the data signal voltage transmitted to the driving transistor.

### CROSS-REFERENCES TO RELATED APPLICATIONS

This application claims priority of Chinese Patent Application No. 201710015814.6, filed on Jan. 10, 2017, the entire contents of which are hereby incorporated by reference.

### FIELD OF THE DISCLOSURE

The present disclosure generally relates to the field of display technology and, more particularly, relates to an organic light-emitting pixel driving circuit, a driving method thereof, and an organic light-emitting display panel.

### BACKGROUND

An organic light-emitting display panel uses an organic light-emitting element to display images. The organic light-emitting display panel has been increasingly and widely applied to various kinds of electronic devices because of advantages such as fast response and low power consumption, etc.

Often, a display panel of the organic light-emitting display device includes a plurality of pixels arranged in a matrix, and each of the plurality of pixels includes an organic light-emitting element. Accordingly, the quality of the working status of the organic light-emitting element may directly impact the evenness and brightness of the display panel. The organic light-emitting element is a current-controlled module and is often driven using a current generated by the thin film transistor that is in a saturation state. Restricted by the fabrication process, the threshold voltage |Vth| of the driving transistors, particularly the driving transistors fabricated by the low-temperature poly-silicon (LTPS) technology, have very poor evenness and may even drift, such that different driving currents may be generated when the same grey-scale voltage is inputted. The inconsistency in the driving current may cause the working status of the organic light-emitting element to be unstable, thereby rendering relatively poor evenness in the display brightness of the organic light-emitting display panel.

The disclosed organic light-emitting pixel driving circuit, driving method thereof, and organic light-emitting display panel are directed to solving at least partial problems set forth above and other problems.

### BRIEF SUMMARY OF THE DISCLOSURE

One aspect of the present disclosure provides an organic tight-emitting pixel driving circuit. The organic light-emitting pixel driving circuit comprises a light-emitting element, a driving transistor, a first transistor, a second transistor, a third transistor, a fourth transistor, a fifth transistor, and a capacitor. The driving transistor is configured to drive the light-emitting element to emit light. The first transistor is configured to transmit an initialization voltage to the light-emitting element. The second transistor is configured to transmit the initialization voltage to the driving transistor and compensate a threshold voltage of the driving transistor. The third transistor is configured to transmit a data signal voltage to the driving transistor. The fourth transistor is configured to transmit a first power supply voltage signal to the driving transistor. The fifth transistor is configured to control an electric connection between the driving transistor and an anode of the light-emitting element. The capacitor is configured to store the data signal voltage transmitted to the driving transistor.

Another aspect of the present disclosure provides a driving method of an organic light-emitting pixel driving circuit, comprising an initialization stage, a threshold detection stage, and a pixel light-emitting stage. In the initialization stage, under control of a first scanning signal line, a first transistor is configured to transmit an initialization voltage to an anode of a light-emitting element, and a second transistor is configured to transmit the initialization signal to a gate electrode of a driving transistor, such that the light-emitting element and the driving transistor fulfill initialization. In the threshold detection stage, a third transistor is configured to transmit a data signal voltage to a first electrode of the driving transistor under control of a second scanning signal line, thereby fulfilling threshold detection of the driving transistor. In the pixel light-emitting stage, a fourth transistor is configured to transmit a first power supply voltage signal to the driving transistor under control of a first light-emitting control signal line, and a fifth transistor is configured to control electric connection between a second electrode of the driving transistor and the anode of the light-emitting element under control of a second light-emitting control signal line, such that the driving transistor drives the light-emitting element to emit light.

Another aspect of the present disclosure provides an organic light-emitting display panel. The organic light-emitting display panel comprises a plurality of rows of pixel units, and each row of pixel units includes a plurality of organic light-emitting pixel driving circuits. An organic light-emitting pixel driving circuit comprises a light-emitting element, a driving transistor, a first transistor, a second transistor, a third transistor, a fourth transistor, a fifth transistor, and a capacitor. The driving transistor is configured to drive the light-emitting element to emit light. The first transistor is configured to transmit an initialization voltage to the light-emitting element. The second transistor is configured to transmit the initialization voltage to the driving transistor and compensate a threshold voltage of the driving transistor. The third transistor is configured to transmit a data signal voltage to the driving transistor. The fourth transistor is configured to transmit a first power supply voltage signal to the driving transistor. The fifth transistor is configured to control an electric connection between the driving transistor and an anode of the light-emitting element. The capacitor is configured to store the data signal voltage transmitted to the driving transistor.

Other aspects of the present disclosure can be understood by those skilled in the art in light of the description, the claims, and the drawings of the present disclosure.

### BRIEF DESCRIPTION OF THE DRAWINGS

Other features, goals, and advantages of the present disclosure will become more apparent via a reading of detailed descriptions of non-limiting embodiments with reference to the accompanying drawings.

FIG. 1 illustrates a structural schematic view of an exemplary organic light-emitting pixel driving circuit according to embodiments of the present disclosure;

FIG. 2 illustrates a structural schematic view of another exemplary organic light-emitting pixel driving circuit according to embodiments of the present disclosure;

FIG. 3 illustrates a structural schematic view of another exemplary organic light-emitting pixel driving circuit according to embodiments of the present disclosure;

FIG. 4 illustrates an exemplary timing sequence for driving an organic light-emitting pixel driving circuit illustrated in FIG. 1 and FIG. 2;

FIG. 5 illustrates an exemplary timing sequence for driving an organic light-emitting pixel driving circuit illustrated in FIG. 3;

FIG. 6 illustrates another exemplary timing sequence tor driving an organic light-emitting pixel driving circuit illustrated in FIG. 3;

FIG. 7 illustrates an exemplary flow chart of a driving method for driving an organic light-emitting pixel driving circuit according to embodiments of the present disclosure;

FIG. 8 illustrates a structural schematic view of an exemplary organic light-emitting display panel according to embodiments of the present disclosure; and

FIG 9 illustrates a structural schematic view of another exemplary organic light-emitting display panel according to embodiments of the present disclosure.

### DETAILED DESCRIPTION

Reference will be made in detail with reference to embodiments of the present disclosure as illustrated in the accompanying drawings and embodiments. It should be understood that, specific embodiments described herein are only for illustrative purposes, and are not intended to limit the scope of the present disclosure. In addition, for ease of description, accompanying drawings only illustrate a part of, but not entire structure related to the present disclosure.

It should be noted that as long as no conflict is generated, disclosed embodiments and features of the disclosed embodiments may be combined with each other. Hereinafter, the present disclosure is illustrated in detail with reference to embodiments thereof as illustrated in the accompanying drawings.

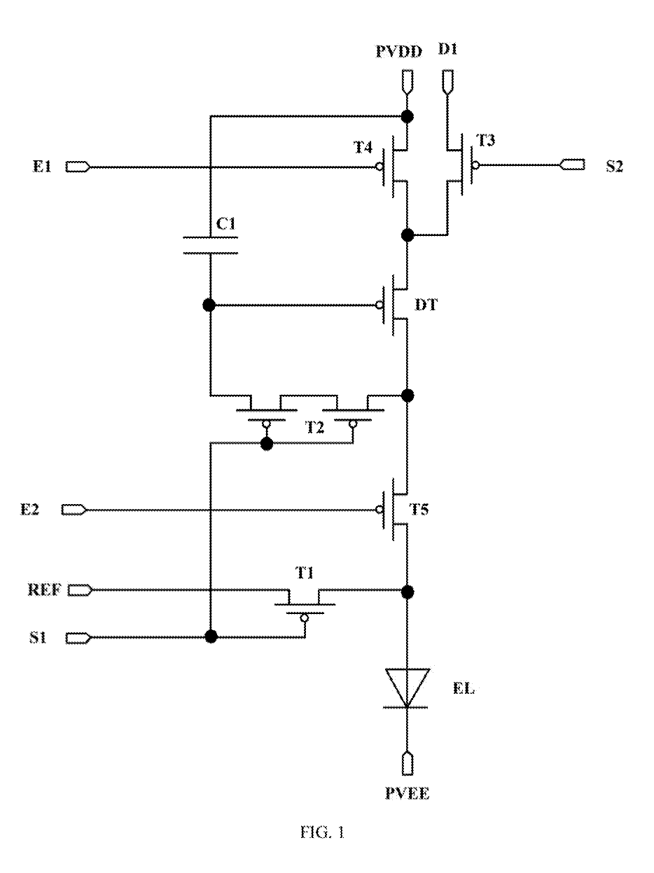

FIG. 1 illustrates a structural schematic view of an exemplary organic light-emitting pixel driving circuit according to embodiments of the present disclosure. As shown in FIG. 1, an organic light-emitting pixel driving circuit may include a first transistor T1, a second transistor T2, a third transistor T3, a fourth transistor T4, a fifth transistor T5, a driving transistor DT, a capacitor C1, and a light-emitting element EL. Optionally, the second transistor T2 may be a dual gate transistor.

Further, the organic light-emitting pixel driving circuit may further include a first scanning signal line S1, a second scanning signal line S2, a first light-emitting control signal line E1, and a second light-emitting control signal line E2. The first scanning signal line S1, the second scanning signal line S2, the first light-emitting control signal line E1, and the second light-emitting control signal line E2 may each be configured to transmit a signal.

In one embodiment, the first transistor T1 may be turned on in response to a signal carried by the first scanning signal line S1, thereby transmitting an initialization voltage to the light-emitting element EL. The second transistor T2 may be turned on in response to the signal carried by the first scanning signal line S1, thereby transmitting the initialization voltage to the driving transistor DT and compensating the threshold voltage of the driving transistor DT. The third transistor T3 may be turned on in response to a signal carried by the second scanning signal line S2, thereby transmitting a data signal voltage to the driving transistor DT.

Further, the fourth transistor T4 may be turned on in response to a signal carried by the first light-emitting control signal line E1, thereby transmitting a first power supply voltage signal to the driving transistor DT. The fifth transistor T5 may be series-coupled between the driving transistor DT and the anode of the light-emitting element EL. When the fifth transistor T5 is turned on in response to the second light-emitting control signal line E2, the driving transistor DT may be electrically connected to the anode of the light-emitting element EL. Further, the capacitor C1 may be configured to store the data signal voltage transmitted to the driving transistor DT. The light-emitting element EL may be configured to emit light in response to the driving current generated by the driving transistor DT.

In some embodiments, as shown in FIG. 1, the organic light-emitting pixel driving circuit may further include an initialization signal line REF, and the aforementioned initialization voltage may be a voltage signal transmitted by the initialization signal line REF. The first transistor T1 may thus be configured to transmit a voltage signal carried by the initialization signal line REF, to the light-emitting element EL, and the second transistor T2 may to thus be configured to transmit the voltage signal carried by the signal line REF to the driving transistor DT.

By utilizing the voltage signal carried by the initialization signal line REF as the initialization signal to initiate the driving transistor DT and the light-emitting element the voltage level of the gate electrode of the driving transistor DT and the voltage level of the anode of the light-emitting element EL may be more stable.

In some embodiments, as shown in FIG. 1, the organic light-emitting pixel driving circuit may further include a data line D1, and a first power supply voltage end PVDD. The data line D1 may be configured to output the data signal voltage, and the first power supply voltage end PVDD may be configured to output the first power supply voltage signal. Optionally, the organic light-emitting pixel driving circuit may further include a second power supply voltage end PVEE, and the second power supply voltage end PVEE may be configured to output a second power supply voltage signal.

More specifically, a first electrode of the first transistor T1 may be electrically connected to the initialization signal line REF, a second electrode of the first transistor T1 may be electrically connected to an anode of the light-emitting element EL, and a gate electrode of the first transistor T1 may be electrically connected to the first scanning signal line S1. A first electrode of the second transistor T2 may be electrically connected to a second electrode of the driving transistor DT, a second electrode of the second transistor T2 may be electrically connected to a gate electrode of the driving transistor DT, and a gate electrode of the second transistor T2 may be electrically connected to the first scanning signal line S1.

Further, a first electrode of the third transistor T3 may be electrically connected to the data line D1, a second electrode of the third transistor T3 may be electrically connected to a first electrode of the driving transistor DT, and a gate electrode of the third transistor T3 may be electrically connected to the second scanning signal line S2. A first electrode of the fourth transistor T4 may be electrically connected to the first power supply voltage end PVDD, a second end of the fourth transistor T4 may be electrically connected to the first electrode of the driving transistor DT, and a gate electrode of the fourth transistor T4 may be electric connected to the first light-emitting control signal line E1.

Further, a first electrode of the filth transistor T5 may be electrically connected to the anode of the light-emitting element EL, a second electrode of the fifth transistor T5 may be electrically connected to the second electrode of the driving transistor DT, and a gate electrode of the fifth transistor T5 may be electrically connected to the second light-emitting control signal E2. A first plate of the capacitor C1 may be electrically connected to the first power supply voltage end PVDD, and a second plate of the capacitor C1 may be electrically connected to the gate electrode of the driving transistor DT. A cathode of the light-emitting element may be electrically connected to the second power supply voltage end PVEE.

More specifically, the first light-emitting control signal line E1 may output a first control signal, and the second light-emitting control signal line E2 may output a second control signal. The second control signal line E2 may control the fifth transistor T5 to be turned off, thereby controlling whether the light-emitting element EL is disconnected to the driving transistor DT or not. Accordingly, the phenomenon that the light-emitting element EL emits light due to the existence of a leakage current may be avoided.

In the aforementioned organic light-emitting pixel driving circuit, the first scanning signal line S1 may be configured to control the first transistor T1 and the second transistor T2 to be turned on. The initialization voltage may be transmitted to initiate the driving transistor DT and the light-emitting element EL. Further, a diode structure formed by the second transistor T2 and the driving transistor DT may be configured to compensate the threshold voltage of the driving transistor DT. Accordingly, the driving current generated by the driving transistor DT may be uniform and stable, thereby improving the display evenness of the organic light-emitting display panel.

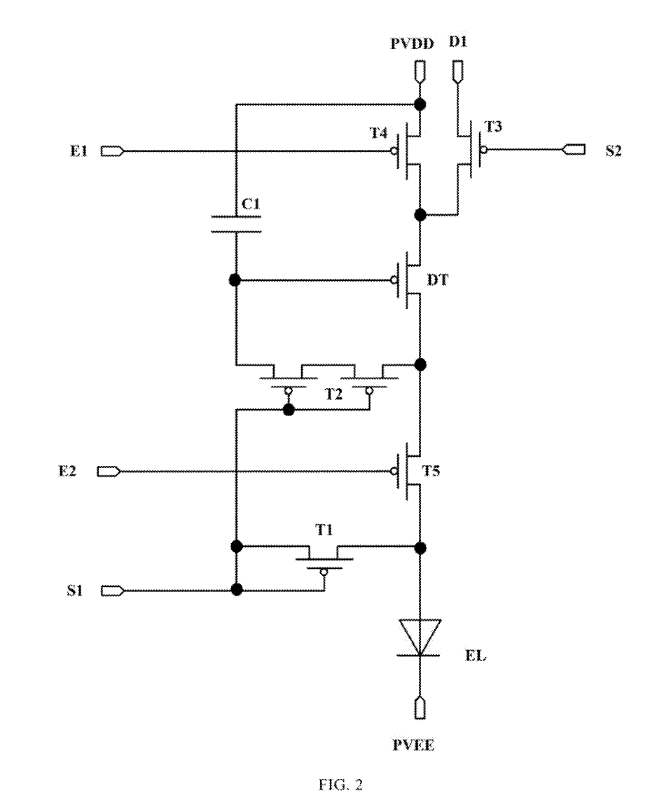

FIG. 2 illustrates a structural schematic view of another exemplary organic light-emitting pixel driving circuit according to embodiments of the present disclosure. Similar to FIG. 1, as shown in FIG. 2, the organic light-emitting pixel driving circuit may include a first transistor T1, a second transistor T2, a third transistor T3, a fourth transistor T4, a fifth transistor T5, a driving transistor DT, a capacitor C1, and a light-emitting element EL. The organic light-emitting pixel driving circuit may further include a first scanning signal line S1, a second scanning signal line S2, a first light-emitting control signal line E1, and a second light-emitting control signal line E2. Optionally, the second transistor T2 may be a dual gate transistor.

In some embodiments, as shown in FIG. 2, the organic light-emitting pixel driving circuit may further include a data line D1, and a first power supply voltage end PVDD. The data line D1 may be configured to output the data signal voltage, and the first power supply voltage end PVDD may be configured to output the first power supply voltage signal. Optionally, the organic light-emitting pixel driving circuit may further include a second power supply voltage end PVEE, and the second power supply voltage end PVEE, may be configured to output a second power supply voltage signal.

More specifically, as shown in FIG. 2, a first electrode and a gate electrode of the first transistor T1 may be electrically connected to the first scanning signal line S1, and a second electrode of the first transistor T1 may be electrically connected to an anode of the light-emitting element EL. A first electrode of the second transistor T2 may be electrically connected to a second electrode of the driving transistor DT, a second electrode of the second transistor T2 may be electrically connected to a gate electrode of the driving transistor DT, and a gate electrode of the second transistor T2 may be electrically connected to the first scanning signal line S1.

Further, a first electrode of the third transistor T3 may be electrically connected to the data line D1, a second electrode of the third transistor T3 may be electrically connected to a first electrode of the driving transistor DT, and a gate electrode of the third transistor T3 may be electrically connected to the second scanning signal line S2. A first electrode of the fourth transistor T4 may be electrically connected to the first power supply voltage end PVDD, a second electrode of the fourth transistor T4 may be electrically connected to the first electrode of the driving transistor DT, and a gate electrode of the fourth transistor T4 may be electrically connected to the first light-emitting control signal line E1.

Further, a first electrode of the fifth transistor T5 may be electrically connected to an anode of the light-emitting element EL, a second electrode of the fifth transistor T5 may be electrically connected to a second electrode of the driving transistor DT, and a gate electrode of the fifth transistor T5 may be electrically connected to the second light-emitting control signal line E2. A first plate of the capacitor C1 may be electrically connected to the first power supply voltage end PVDD, and a second plate of the capacitor C1 may be electrically connected to the gate electrode of the driving transistor DT. A cathode of the light-emitting element EL may be electrically connected to the second power supply voltage end PVEE.

Different from FIG. 1, as shown in FIG. 2, the initialization signal line REF is no longer included in the organic light-emitting pixel driving circuit. Accordingly, the initialization voltage in FIG. 2 may be a voltage signal transmitted by the first scanning signal line S1. Such voltage signal may not only turn on the first transistor T1 and the second transistor T2, but further act as the initialization voltage to initiate the driving transistor DT and the light-emitting element EL.

That is, the first scanning signal line S1 may be configured to output a voltage signal to the driving transistor DT and the light-emitting element. EL to initiate the driving transistor DT and the light-emitting element EL. Because no additional signal line (e.g., the initialization signal line REF) is needed to provide the initialization voltage, the layout area of the organic light-emitting pixel driving circuit may be reduced.

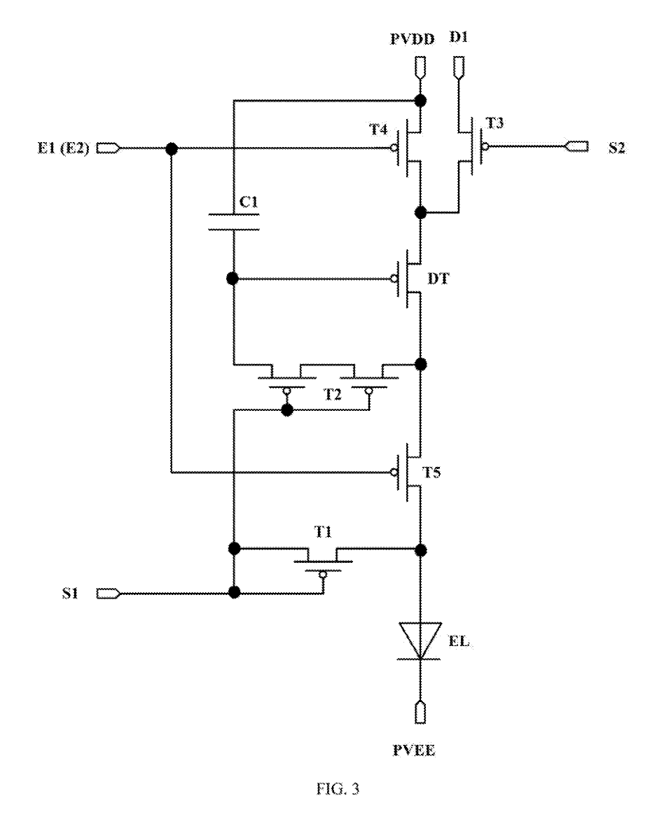

FIG. 3 illustrates a structural schematic view of another exemplary organic light-emitting pixel driving circuit according to embodiments of the present disclosure. Similar to FIG. 2, the organic light-emitting pixel driving circuit illustrated in FIG. 3 may include a first transistor T1, a second transistor T2, a third transistor T3, a fourth transistor T4, a fifth transistor TS, a driving transistor DT, a capacitor C1, and a light-emitting element EL. Optionally, the second transistor T2 may be a dual gate transistor. The organic light-emitting pixel driving circuit may further include a first scanning signal line S1, a second scanning signal line S2, a first light-emitting control signal line E1, and a second light-emitting control signal line E2.

In some embodiments, as shown in FIG. 3, the organic light-emitting pixel driving circuit may further include a data line D1, and a first power supply voltage end PVDD. The data line D1 may be configured to output the data signal voltage, and the first power supply voltage end PVDD may be configured to output a first power supply voltage signal. Optionally, the organic light-emitting pixel driving circuit may further include a second power supply voltage end PVEE, and the second power supply voltage end PVEE may be configured to output a second power supply voltage signal.

Different from FIG. 2, in FIG. 3, the first light-emitting control signal line E1 may be multiplexed as the second light-emitting control signal line E2. That is, the gate electrode of the fifth transistor T5 may be electrically connected to the first light-emitting control signal line E1, and the first light-emitting control signal line E1 may output a first control signal.

Because the first light-emitting signal line E1 is multiplexed as the second light-emitting control signal line E2 to output the first control signal, as shown in FIG. 3, only one light-emitting control signal line may be needed in the organic light-emitting pixel driving circuit to simultaneously control the gate electrode of the fourth transistor T4 and the gate electrode of the fifth transistor T5. Accordingly, the area occupied by the organic light-emitting pixel driving circuit may be further reduced.

Though in the driving circuit diagrams illustrated in FIG. 1, FIG. 2, and FIG. 3, the first transistor T1, the second transistor T2, the third transistor T3, the fourth transistor T4, the fifth transistor T5, and the driving transistor DT are all P-type transistors (e.g., PMOS transistors), the present disclosure is not intended to be limiting. That is, in practical applications, the first transistor T1, the second transistor T2, the third transistor T3, the fourth transistor T4, the fifth transistor T5, and the driving transistor DT may all be N-type transistors (e.g., NMOS transistor), or partially P-type transistors and partially N-type transistors.

Optionally, by using the same type of transistors in the organic light-emitting pixel driving circuit, the transistors in such driving circuit may be fabricated simultaneously, thereby simplifying the fabrication processes of the pixel driving circuit.

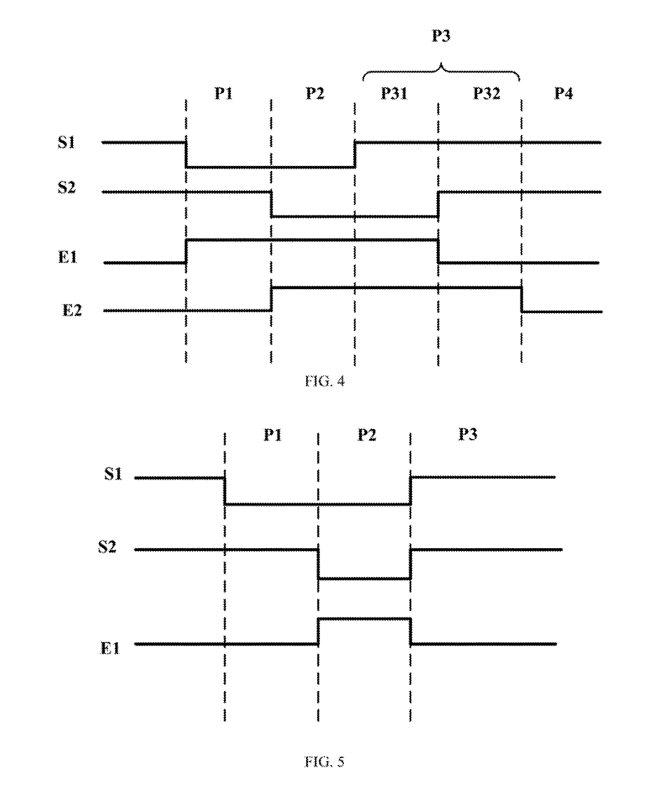

Hereinafter, the first transistor T1, the second transistor T2, the third transistor T3, the fourth transistor T4, the fifth transistor T5, and the driving transistor DT are all assumed to be PMOS transistors for illustrative purposes. Further, FIG. 4 illustrates an exemplary timing sequence for driving an organic light-emitting pixel driving circuit illustrated in FIG. 1 and FIG. 2. That is, the working principles of the organic light-emitting pixel driving circuit shown in FIG. 1 and FIG. 2 may be described hereinafter with reference to the timing sequence illustrated in FIG. 4.

As shown in FIG. 4 and referring to FIG. 1, the timing sequence may include a first stage P1, a second stage P2, a third stage P3, and a fourth stage P4. In particular, the third stage P3 may further include two sub-stages P31 and P32.

In the first stage P1, a low voltage level signal VGL may be supplied to the first scanning signal line S1 and the second light-emitting control signal line E2, thereby turning on the first transistor T1, the second transistor T2, and the fifth transistor T5. A high voltage level signal VGH may be supplied to the second scanning signal line S2 and the first light-emitting control signal line E1, thereby turning off the third transistor T3 and the fourth transistor T4.

Further, in the first stage P1, an initialization signal Vref may be supplied to the initialization signal line REF. Because the first transistor T1 is turned on, the voltage level of the anode of the light-emitting element EL may be thus equal to Vref. Further, because the fifth transistor T5 and the second transistor T2 are turned on, the voltage level Vg of the gate electrode of the driving transistor DT may also be equal to Vref.

In the second stage P2, a low voltage level signal VGL may be supplied to the first scanning signal line S1 and the second scanning signal line S2, thereby turning on the first transistor T1, the second transistor T2, and the third transistor T3. A high voltage level signal VGH may be supplied to the first light-emitting control line E1 and the second light-emitting control signal line E2, thereby turning off the fourth transistor T4 and the fifth transistor T5.

Further, in the second stage P2, a data signal voltage Vdata may be supplied to the data line D1, and the initialization signal Vref may be supplied to the initialization signal line REF. Because the third transistor T3 is turned on, the voltage level Vs of the first electrode (e.g., the source electrode) of the driving transistor DT may be equal to Vdata. Further, because the second transistor T2 is turned on and the fifth transistor T5 is turned off, the voltage level of the gate electrode of the driving transistor DT may reach a value of Vdata−|Vth|, where |Vth| is a threshold voltage of the driving transistor DT.

In the first sub-stage P31 of the third stage P3, a low voltage level signal VGL may be supplied to the second scanning signal line S2, and a high voltage level signal VGH may be supplied to the first scanning signal line S1, the first light-emitting control signal line E1, and the second light-emitting control signal line E2. Accordingly, the third transistor T3 may be turned on, and the first transistor T1, the second transistor T2, the fourth transistor T4, and the fifth transistor T5 may be turned off. Further, the voltage level of the gate electrode of the driving transistor DT may remain to be Vdata−|−Vth|.

In the second sub-stage P32 of the third stage P3, a low voltage level signal VGL may be supplied to the first light-emitting control signal line E1, and a high voltage level signal VGH may be supplied to the first scanning signal line S1, the second scanning signal line S2, and the second light-emitting control signal line E2. Accordingly, the fourth transistor T4 may be turned on, and the first transistor T1, the second transistor T2, the third transistor T3, and the fifth transistor T5 may be turned off.

Further, in the second sub-stage P32, a first power supply voltage signal PVDD may be supplied to the first power supply voltage end PVDD. Because the fourth transistor T4 is turned on, the voltage level Vs of the first electrode (e.g., the source electrode) of the driving transistor DT may be equal to PVDD. Further, the voltage level Vg of the gate electrode of the driving transistor DT may remain to be Vdata−|Vth|.

In the fourth stage P4, a low voltage level signal VGL may be supplied to the first light-emitting control signal line E1 and the second light-emitting control signal line E1 thereby turning on the fourth transistor T4 and the fifth transistor T5. A high voltage level signal VGH may be supplied to the first scanning signal line S1 and the second scanning signal line S2, thereby turning off the first transistor T1, the second transistor T2, and the third transistor T3.

Further, in the fourth stage P4, the first power supply voltage PVDD may be supplied to the first power supply voltage end PVDD. Because the fourth transistor T4 is turned on and due to the coupling effect of the capacitor C1, the voltage level Vs of the first electrode (e.g., the source electrode) of the driving transistor DT may still be equal to PVDD, and the voltage level Vg of the gate electrode of the driving transistor DT may still be equal to Vdata−|Vth|. Further, the driving transistor DT may be turned on, and because the fifth transistor T5 is also turned on, the light-emitting element EL may emit light.

As seen from the equation of light-emitting current (i.e., Ioled∞(Vsg−|Vth|)²), in the fourth stage P4, the light-emitting current Ioled that flows through the light-emitting element EL may be proportional to the square of the difference between the gate-source voltage Vsg and the threshold voltage |Vth| of the driving transistor DT. In particular, the gate-source voltage Vsg may refer to a voltage difference between the gate electrode and the source electrode of the driving transistor DT. That is, the gate-source voltage Vsg of the driving transistor DT may equal to Vs−Vg (i.e., Vsg=Vs−Vg).

Further, because in the fourth stage P4, the voltage level Vs of the first electrode (e.g., the source electrode) of the driving transistor DTs equal to PVDD and the voltage level Vg of the gate electrode of the driving transistor DT is equal to Vdata−|Vth|, the aforementioned light-emitting current Ioled (i.e., the driving current) may be expressed as follows:

Ioled∞(Vsg−|Vth|)²=(Vs−Vg−|Vth|)²=(PVDD−Vdata+|Vth|−|Vth|)²=(PVDD−Vdata)².

From the above-described equation, the light-emitting current (i.e., the driving current) Ioled of the light-emitting element EL may not be related to the threshold voltage |Vth| of the driving transistor DT, and the compensation for the threshold voltage |Vth| of the driving transistor DT may be realized.

In some embodiments, the organic light-emitting pixel driving circuit shown in FIG. 2 may also be driven by the timing sequence illustrated in FIG. 4. Further, when the timing sequence in FIG. 4 is applied to drive the organic light-emitting pixel driving circuit shown in FIG. 2, the corresponding working process of stages P2-P4 may be the same as or similar to the working process of stages P2-P4 when the timing sequence in FIG. 4 is applied to drive the organic light-emitting pixel driving circuit illustrated in FIG. 1. Further, the generated light-emitting current Ioled may also be the same.

Different from using the timing sequence in FIG. 4 to drive the organic light-emitting pixel driving circuit illustrated in FIG. 1, as shown FIG. 4 and referring to FIG. 2, in the first stage, the initialization signal line REF may be no longer included in the organic light-emitting pixel driving circuit illustrated in FIG. 2 to receive an initialization signal Vref.

More specifically, in the first stage, a low voltage level signal VGL may be supplied to the first scanning signal line S1 and the second light-emitting control signal line E2, thereby turning on the first transistor T1, the second transistor T2, and the fifth transistor T5. A high voltage level signal VGH may be supplied to the second scanning signal line S2 and the first light-emitting control signal line E1, thereby turning off the third transistor T3 and the fourth transistor T4. Because the first transistor T1 is turned on, the voltage level or the anode of the light-emitting element EL may equal to the voltage level of the low voltage level signal VGL carried by the first scanning signal line S1. Further, because the second transistor T2 and the fifth transistor T5 are turned on, the low voltage level signal VGL may be transmitted to the gate electrode of the driving transistor DT. Accordingly, the voltage level of the gate electrode of the driving transistor DT may equal to the voltage level of the low voltage level signal VGL carried by the first scanning signal line S1.

FIG. 5 illustrates an exemplary timing sequence for driving an organic light-emitting pixel driving circuit illustrated in FIG. 3. The same as that illustrated in FIG. 1 and FIG. 2, the first transistor T1, the second transistor T2, the third transistor T3, the fourth transistor T4, the fifth transistor T5, and the driving transistor DT in FIG. 3 may also all be P-type transistors (e.g., PMOS transistors). Further, referring to FIG. 5, working principles of the pixel driving circuit shown in FIG. 3 is described hereinafter in detail. For example, the timing sequence for driving an organic light-emitting pixel driving circuit illustrated in FIG. 3 may include a first stage P1, a second stage P2, and a third stage P3.

In the first stage P1, the low voltage level signal may be supplied to the first scanning signal line S1 and the first light-emitting control signal line E1, thereby turning on the first transistor T1, the second transistor T2, the fourth transistor T4, and the fifth transistor T5. The high voltage level signal VGH may be supplied to the second scanning signal line S2, thereby turning off the third transistor T3. Further, the first power supply voltage PVDD may be supplied to the first power supply voltage end PVDD.

Because the fourth transistor T4 is turned on, the voltage level Vs of the first electrode (e.g., the source electrode) of the driving transistor DT may be PVDD. Further, because the first transistor T1 is turned on, the voltage level of the anode of the light-emitting element EL may equal to the voltage level of the low voltage level signal VGL carried by the first scanning signal line S1.

Further, because the fifth transistor T5 and the second transistor T2 are turned on, the voltage level Vg of the gate electrode of the driving transistor DT may equal to the voltage level of the low voltage level signal VGL carried by the first scanning signal line S1. By then, the driving transistor DT may be turned on. Further, because the voltage level of the anode of the light-emitting element EL is the low voltage level signal VGL, the voltage difference between the anode and the cathode is too low to drive the light-emitting element EL, thus, the light-emitting element EL may not emit light.

In the second stage P2, the low voltage level signal VGL may be supplied to the first scanning signal line S1 and the second scanning signal line S2, thereby turning on the first transistor T1, the second transistor T2, and the third transistor T3. The high voltage level signal VGH may be supplied to the first light-emitting control signal E1, thereby turning off the fourth transistor T4 and the fifth transistor T5. The data signal voltage Vdata may be supplied to the data signal line D1, and because the third transistor T3 is turned on, the voltage level Vs of the first electrode (e.g., the source electrode) of the driving transistor may be equal to Vdata.

Further, the voltage level of the gate electrode (e.g., the source electrode) of the driving transistor DT may reach Vdata−|Vth|, where |Vth| is the threshold voltage of the driving transistor DT. By then, the anode of the light-emitting element EL may still receive the low voltage level signal VGL carried by the first scanning signal line S1, and the light-emitting element EL may not emit light.

In the third stage P3, the low voltage level signal VGL may be supplied to the first light-emitting control signal line E1, thereby turning on the fourth transistor T4 and the fifth transistor T5. The high voltage level signal VGH may be supplied to the first scanning signal line S1 and the second scanning signal line S2, thereby turning off the first transistor T1, the second transistor T2, and the third transistor T3.

Further, in the third stage P3, the first power supply voltage PVDD may be supplied to the first power supply voltage end PVDD, and because the fourth transistor T4 is turned on, the voltage level Vs of the first electrode (e.g., the source electrode) of the driving transistor DT may be equal to PVDD. The voltage level Vg of the gate electrode of the driving transistor DT may be equal to Vdata−|Vth|. By then, the driving transistor DT may be turned on, a driving current may be generated, and the light-emitting element EL may emit light.

From the equation of light-emitting current, in the third stage P3, the light-emitting current (i.e., the driving current) Ioled that flows through the light-emitting element EL may be proportional to the square of the difference between the gate-source voltage Vsg (the voltage difference between the gate electrode and the source electrode) and the threshold voltage |Vth| of the driving transistor DT. More specifically, the gate-source voltage Vsg of the driving transistor DT may equal to Vs−Vg (i.e., Vsg=Vs−Vg). Accordingly, the aforementioned driving current may be expressed as follows:

Ioled∞(Vsg−|Vth|)²=(Vs−Vg−|Vth|)²=(PVDD−Vdata+|Vth|−|Vth|)²=(PVDD−Vdata)².

From the above-described equation, the driving current Ioled of the light-emitting element EL may not be related to the threshold voltage |Vth| of the driving transistor DT, and the compensation for the threshold voltage of the driving transistor DT may be realized.

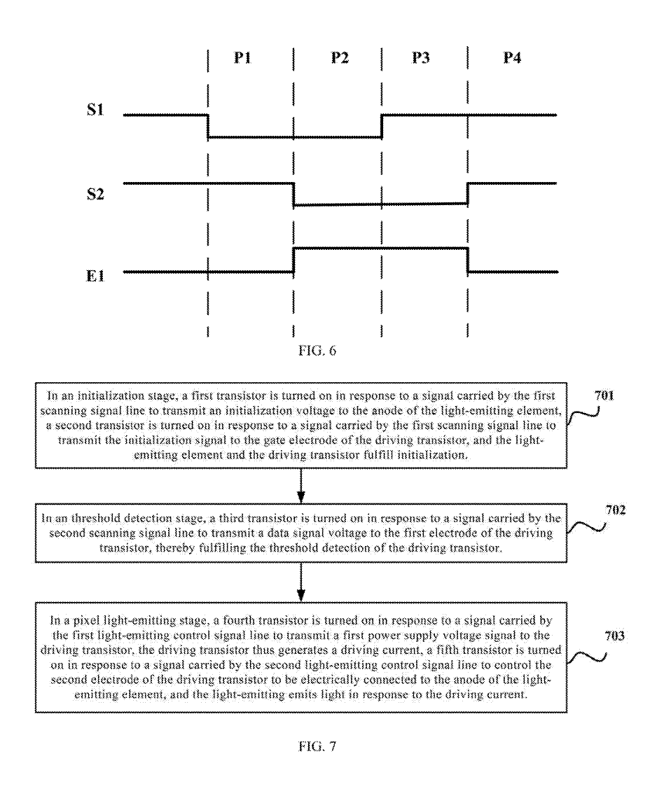

FIG. 6 illustrates another exemplary timing sequence for driving an organic light-emitting pixel driving circuit illustrated in FIG. 3. That is, in some embodiments, the organic light-emitting pixel driving circuit illustrated in FIG. 3 may be driven by the timing sequence in FIG. 6. As shown in FIG. 6, the timing sequence may include a first stage P1, a second stage P2, a third stage P3, and a fourth stage P4.

More specifically, in the first stage P1, the low voltage level signal VGL may be supplied to the first scanning signal line S1 and the first light-emitting control signal line E1, thereby turning on the first transistor T1, the second transistor T2, the fourth transistor T4, and fifth transistor T5. The high voltage level signal may be supplied to the second scanning signal line S2, thereby turning off the third transistor T3. The first power supply voltage PVDD may be supplied to the first power supply voltage end PVDD.

Accordingly, the voltage level Vs of the first electrode (e.g., the source electrode) of the driving transistor DT may be equal to PVDD. The voltage level Vg of the gate electrode of the driving transistor DT and the voltage level of the anode of the light-emitting element EL may be equal to the voltage level of the low voltage level signal VGL carried by the first scanning signal line S1. By then, the driving transistor DT may be turned on. Because the voltage level (VGL) of the anode of the light-emitting element EL is lower than the voltage level of the second power supply voltage end PVEE, the light-emitting element EL may not emit light.

In the second stage P2, the low voltage level signal VGL may be supplied to the first scanning signal line S1 and the second scanning signal line S2, thereby turning on the first transistor T1, the second transistor T2, and the third transistor T3. The high voltage level signal VGH may be supplied to the first light-emitting control signal line E1, thereby turning off the fourth transistor T4 and the fifth transistor T5. Further, the data signal voltage Vdata may be supplied to the data D1.

Accordingly, the voltage level Vs of the first electrode (e.g., the source electrode) of the driving transistor DT may be equal to Vdata, and the voltage level of the gate electrode of the driving transistor DT may reach Vdata−|Vth|. The |Vth| here may refer to the threshold voltage of the driving transistor DT. By then, the anode of the light-emitting element EL may still receive the low voltage signal VGL outputted by the first scanning signal line S1, and the light-emitting element EL may not emit light.

In the third stage P3, the low voltage level signal VGL may be supplied to the second scanning signal line S2, thereby turning on the third transistor T3. The high voltage level signal VGH may be supplied to the first scanning signal line S1 and the first light-emitting control signal line E1, thereby turning off the first transistor T1, the second transistor T2, the fourth transistor T4, and the fifth transistor TS. Further, the data signal voltage Vdata may be supplied to the data line D1. Accordingly, the voltage level of the first electrode (e.g., the source electrode) of the driving transistor DT may be equal to Vdata.

In the fourth stage P4, the low voltage level signal VGL may be supplied to the first light-emitting control signal line E1, thereby turning on the fourth transistor T4 and the fifth transistor T5. The high voltage level signal VGH may be supplied to the first scanning signal line S1 and the second scanning signal line S2, thereby turning off the first transistor T1, the second transistor T2, and the third transistor T3. Further, the first power supply voltage PVDD may be supplied to the first power supply voltage end PVDD.

Accordingly, the voltage level Vs of the first electrode (e.g., the first electrode) of the driving transistor DT may be equal to PVDD. The voltage level Vg of the gate electrode of the driving transistor DT may be Vdata−|Vth|. The driving transistor DT may be turned on, and a driving current may be generated, such that the light-emitting element EL may emit light.

Accordingly, the light-emitting current (i.e., the driving current) Ioled that generated by the driving transistor DT may be proportional to the square of the difference between the gate-source voltage Vsg (the voltage difference between the gate electrode and the source electrode) of the driving transistor DT and the threshold voltage |Vth|. More specifically, the aforementioned driving current may be expressed as follows:

Ioled∞(Vsg−|Vth|)²=(Vs−Vg−|Vth|)²=(PVDD−Vdata+|Vth|−|Vth|)²=(PVDD−Vdata)².

From the above-described equation, the driving current Ioled of the light-emitting element EL may not be related to the threshold voltage |Vth| of the driving transistor DT, and the compensation for the threshold voltage of the driving transistor DT may be realized.

Referring to FIG. 1, FIG. 2, FIG. 3, and corresponding timing sequences, when the same first power supply voltage signal PVDD and the same data signal Vdata are supplied to the disclosed organic light-emitting pixel driving circuit, the same light-emitting current Ioled may be generated. Thus, the impacts of the threshold voltage of the driving transistor DT on the light-emitting current Ioled may be avoided.

Accordingly, when the aforementioned organic light-emitting pixel driving circuit is applied to the organic light-emitting display panel, the signal line that outputs an initialization signal and the signal line that controls the fifth transistor T5 may be configured based on the specific arrangement condition of the display panel, such that the disclosed organic light-emitting pixel driving circuit may have a broader application range.

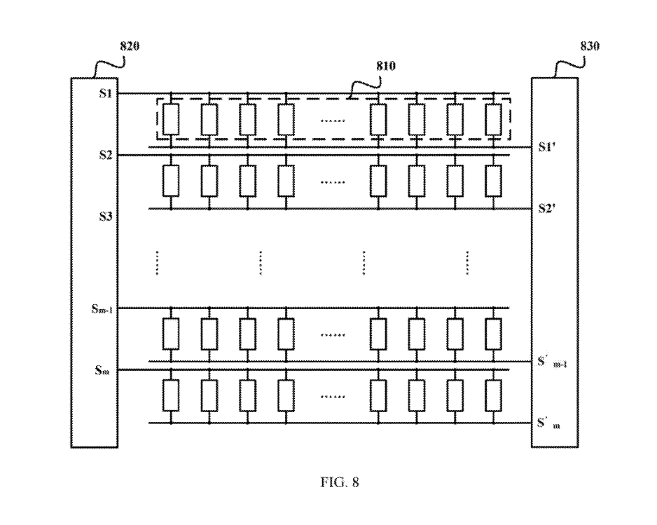

Further, the present disclosure also provides a driving method of an organic light-emitting pixel driving circuit. The disclosed driving method may be configured to drive the aforementioned organic light-emitting pixel driving circuit. FIG. 7 illustrates an exemplary flow chart of a driving method for driving an organic light-emitting pixel driving circuit in one frame period according to embodiments of the present disclosure. As shown in FIG. 7, the driving method may include the following steps.

Step 701: In an initialization stage, a first transistor is configured to transmit an initialization voltage to an anode of the light-emitting element in response to a signal carried by the first scanning signal line, a second transistor is configured to transmit the initialization signal to the gate electrode of the driving transistor in response to a signal carried by the first scanning signal line, and the light-emitting element and the driving transistor fulfill initialization.

Step 702: In an threshold detection stage, a third transistor is configured to transmit a data signal voltage to the first electrode of the driving transistor in response to a signal carried by the second scanning signal line, thereby fulfilling the threshold detection of the driving transistor.

Step 703: In a pixel light-emitting stage, a fourth transistor is configured to transmit a first power supply voltage signal to the driving transistor in response to a signal carried by the first light-emitting control signal line, and the driving transistor generates a driving current. Further, in step 703, a fifth transistor is configured to control the electric connection between the second electrode of the driving transistor and the anode of the light-emitting element in response to a signal carried by the second light-emitting control signal line, and the light-emitting emits light in response to the driving current.

Optionally, when the driving method of the disclosed organic light-emitting pixel driving circuits is applied to the organic light-emitting pixel driving circuits illustrated in FIG. 1 and FIG. 2, the timing sequence of each signal mentioned in Step 701˜Step 703 may refer to FIG. 4. Optionally, when the driving method of the disclosed organic light-emitting pixel driving circuit is applied to the organic light-emitting pixel driving circuits illustrated in FIG. 3, the timing sequence of each signal mentioned in Step 701˜Step 703 may refer to FIG. 5 or FIG. 6.

Further, when the aforementioned driving method is applied to the organic light-emitting pixel driving circuits illustrated in FIG. 1, in the initial stage, the initialization voltage of the anode of the light-emitting element EL and the initialization voltage of the gate electrode of the driving transistor DT may be a voltage signal carried by the initialization signal line REF. When the aforementioned driving method is applied to the organic light-emitting pixel driving circuits illustrated in FIG. 2 or FIG. 3, in the initialization stage, the initialization voltage of the anode of the light-emitting element EL and the initialization voltage of the gate electrode of the driving transistor DT may be a voltage signal carried by the first scanning signal line S1.

Optionally, when the driving method is applied to the organic light-emitting pixel driving circuits illustrated in FIG. 1 or FIG. 2, the first light-emitting control signal line E1 may output a first control signal, and the second light-emitting control signal E2 may output a second control signal. The signal carried by the first scanning signal line S1 may be delayed for a preset period of time with respect to the signal carried by the second scanning signal line S2. Further, the aforementioned driving method may optionally further include a voltage level holding stage.

More specifically, in the voltage level holding stage, the first transistor T1 and the second transistor T2 may be turned off in response to the high voltage level signal VGH outputted by the first scanning signal line S1, and the fifth transistor T5 may be turned off in response to the high voltage level signal carried by the second light-emitting control signal line E2. Further, the voltage levels of the gate electrode of the driving transistor DT and the anode of the light-emitting element EL may remain substantially unchanged.

Optionally, when the aforementioned driving method is applied to the organic light-emitting pixel driving circuits illustrated in FIG. 3, the first light-emitting control signal line E1 may be multiplexed as the second light-emitting control signal line E2 and output the first control signal. With respect to the signal carried by the second scanning signal line S2, the signal carried by the first scanning signal line S1 may be delayed for a preset period of time. Further, the aforementioned driving method may optionally further include a voltage level holding stage.

More specifically, in the voltage level holding stage, the fourth transistor T4 and the fifth transistor T5 may be turned off in response to the first control signal carried by the first light-emitting control signal line. Further, the first transistor T1 and the second transistor T2 may be turned off in response to the first scanning signal line S1, and the third transistor T3 may be turned on in response to the second scanning signal line S2. Further, the voltage levels of the source electrode of the driving transistor DT, the gate electrode of the driving transistor DT, and the anode of the light-emitting element EL may remain substantially unchanged.

The present disclosure also provides an organic light-emitting display panel. FIG. 8 illustrates a schematic view of an exemplary organic light-emitting display panel according to embodiments of the present disclosure. As shown in FIG. 8, the organic light-emitting display panel may include a plurality of rows of pixel units 810. Each pixel unit in the plurality of rows of pixel units 810 may include an organic light-emitting pixel driving circuit. Optionally, the organic light-emitting display panel may further include a first shift register 820, and a second shift register 830.

Each row of pixel units may be connected to a first scanning signal line and a second scanning signal line. For example, in one embodiment, signals carried by the first scanning signal lines S1˜Sm and signals carried by the second scanning signal lines S1′˜Sm′ may be generated by the first shift register 820 and the second shift register 830, respectively. Further, the signals carried by the first scanning signal lines S1˜Sm and the signals carried by the second scanning signal lines S1′˜Sm′ may have the same waveforms as that of S1 and S2 in FIG. 4 or FIG. 6. In particular, the signals carried by the first scanning signal lines S1˜Sm may have the same waveform as the waveform of S1, and the signals carried by the second scanning signal lines S1′˜Sm′ may have the same waveform as the waveform of S2.

In the disclosed organic light-emitting display panel, by using the aforementioned organic light-emitting pixel driving circuit, the layout area occupied by the pixel driving circuit in the display panel may be relatively small, thereby facilitating the implementation of high PP1 display panels. Further, because the aforementioned organic light-emitting pixel driving circuit may realize the threshold compensation of the driving transistor, the brightness and evenness of the organic light-emitting display panel may be improved.

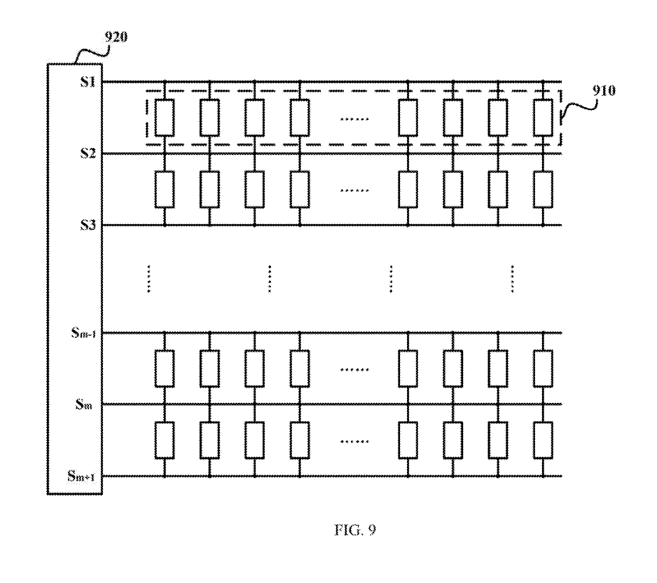

FIG. 9 illustrates a schematic view of another exemplary organic light-emitting display panel according to embodiments of the present disclosure. Similar to FIG. 8, as shown in FIG. 9, the organic light-emitting display panel may include a plurality of rows of pixel units 910. Each row of pixel units 910 may include a plurality of organic light-emitting pixel driving circuits. For example, each pixel unit in each row of pixel units 910 may include an organic light-emitting pixel driving circuit. Further, each row of pixel units, may be connected to a first scanning signal line and a second scanning signal line. Optionally, the organic light-emitting display panel may further include a shift register 920.

Different from FIG. 8, as shown in FIG. 9, the second scanning signal line connected to an i^{th} row of pixel units may be multiplexed as the first scanning signal line connected to an (i+1)^{th} row of pixel units, where i is a positive integer. For example, when the organic light-emitting display panel uses a pixel driving circuit illustrated in FIG. 1 or FIG. 2, the timing sequence of the driving circuit of the i^{th} row of pixel units may refer to FIG. 4. Further, the second scanning signal line connected to the i^{th} row of pixel units may be multiplexed as the first scanning signal line connected to the (i+1)^{th} row of pixel units.

For example, when the organic light-emitting display panel uses a pixel driving circuit illustrated in FIG. 3, the timing sequence of the driving circuit of the i^{th} row of pixel units may refer to FIG. 6. Further, the second scanning signal line connected to the i^{th} row of pixel units may be multiplexed as the first scanning signal line connected to the (i+1)^{th} row of pixel units.

As such, when the disclosed organic light-emitting pixel driving circuit is applied to the disclosed display panel (e.g., a touch-control display panel), a scanning signal line disposed between two adjacent rows of pixel units may be multiplexed.

More specifically, for example, as shown in FIG. 9, the second scanning signal line S2 connected to the first row of pixel units may be multiplexed as the first scanning signal line connected to the second row of pixel units. Accordingly, the first scanning signals and the second scanning signals needed for each organic light-emitting pixel driving circuit may be generated using the same shift register 920. Thus, the layout area occupied by the circuit (e.g., the pixel driving circuit) in the organic light-emitting display panel may be further reduced.

It should be noted that, the above detailed descriptions illustrate only preferred embodiments of the present disclosure and technologies and principles applied herein. Those skilled in the art can understand that the present disclosure is not limited to the specific embodiments described herein, and numerous significant alterations, modifications and alternatives may be devised by those skilled in the art without departing from the scope of the present disclosure. Thus, although the present disclosure has been illustrated in above-described embodiments in details, the present disclosure is not limited to the above embodiments. Any equivalent or modification thereof, without departing from the spirit and principle of the present invention, falls within the true scope of the present invention, and the scope of the present disclosure is defined by the appended claims.

What is claimed is:

1. An organic light-emitting pixel driving circuit, comprising:
a light-emitting element;
a driving transistor, configured to drive the light-emitting element to emit light;
a first transistor, configured to transmit an initialization voltage to the light-emitting element;
a second transistor, configured to transmit the initialization voltage to the driving transistor and compensate a threshold voltage of the driving transistor;
a third transistor, configured to transmit a data signal voltage to the driving transistor;
a fourth transistor, configured to transmit a first power supply voltage signal to the driving transistor;
a firth transistor, configured to control an electric connection between the driving transistor and an anode of the light-emitting element; and
a capacitor, configured to store the data signal voltage transmitted to the driving transistor.

2. The organic light-emitting pixel driving circuit according to claim 1, wherein:
the first transistor and the second transistor are under control of a first scanning signal line;
the third transistor is under control of a second scanning signal line;
the fourth transistor is under control of a first light-emitting control signal line; and
the fifth transistor is under control of a second light-emitting control signal line and is coupled between the driving transistor and the anode of the light-emitting element.

3. The organic light-emitting pixel driving circuit according to claim 2, wherein:
the initialization voltage is a voltage signal transmitted by the first scanning signal line.

4. The organic light-emitting pixel driving circuit according to claim 3, further comprising a data line and a first power supply voltage end, wherein:
the data line is configured to output the data signal voltage, and the first power supply voltage end is configured to output the first power supply voltage signal;
a gate and a first electrodes of the first transistor are connected to the first scanning signal line, and a second electrode of the first transistor is connected to the anode of the light-emitting element;
a first and a second electrodes of the second transistor are connected to a second and a gate electrodes of the driving transistor, respectively, and a gate electrode of the second transistor is connected to the first scanning signal line;
a first electrode of the third transistor is connected to the data line, a second electrode of the third transistor is connected to a first electrode of the driving transistor, and a gate electrode of the third transistor is connected to the second scanning signal line;
a first electrode of the fourth transistor is connected to the first power supply voltage line, a second electrode of the fourth transistor is connected to the first electrode of the driving transistor, and a gate electrode of the fourth transistor is connected to the first light-emitting control signal line;
a first electrode of the fifth transistor is connected to the anode of the light-emitting element, a second electrode of the fifth transistor is connected to the second electrode of the driving transistor, and a gate electrode of the fifth transistor is connected to the second light-emitting control signal line;
the capacitor is connected between the first power supply voltage end and the gate electrode of the driving transistor; and
a cathode of the light-emitting element is connected to a second power supply voltage end.

5. The organic light-emitting pixel driving circuit according to claim 3, wherein;
the first light-emitting control signal line is configured to output a first control signal, and the second light-emitting control signal line is configured to output a second control signal.

6. The organic light-emitting pixel driving circuit according to claim 3, wherein:
the first light-emitting control signal is multiplexed as the second light-emitting control signal line, thereby outputting a first control signal.

7. The organic light-emitting pixel driving circuit according to claim 1, further comprising:
an initialization signal line, wherein the initialization voltage is a voltage signal transmitted by the initialization signal line.

8. The organic light-emitting pixel driving circuit according to claim 7, further comprising a data line and a first power supply voltage end, wherein:
the data line is configured to output the data signal voltage, and the first power supply voltage end is configured to output the first power supply voltage signal;
a first electrode of the first transistor is connected to the initialization signal line, a second electrode of the first transistor is connected to the anode of the light-emitting element, and a gate electrode of the first transistor is connected to the first scanning signal line;
a first and a second electrodes of the second transistor is connected to a second and a gate electrodes of the driving transistor, respectively, and a gate electrode of the second transistor is connected to the first scanning signal line;
a first electrode of the third transistor is connected to the data line, a second electrode of the third transistor is connected to a first electrode of the driving transistor, and a gate electrode of the third transistor is connected to the second scanning signal line;
a first electrode of the fourth transistor is connected to the first power supply voltage end, a second electrode of the fourth transistor is connected to a first electrode of the driving transistor, and a gate electrode of the fourth transistor is connected to the first light-emitting control signal line;
a first electrode of the fifth transistor is connected to the anode of the light-emitting element, a second electrode of the fifth transistor is connected to a second electrode of the driving transistor, and a gate electrode of the fifth transistor is connected to the second light-emitting control signal line;
the capacitor is connected between the first power supply voltage end and the gate electrode of the driving transistor; and
a cathode of the light-emitting element is connected to a second power supply voltage end.

9. The organic light-emitting pixel driving circuit according to claim 1, wherein:
the second transistor is a dual gate transistor.

10. The organic light-emitting pixel driving circuit according to claim 1, wherein;
the first transistor, the second transistor, the third transistor, the fourth transistor, and the fifth transistor are all P-type transistors, or all N-type transistors, or partially P-type transistors and partially N-type transistors.

11. A driving method of an organic light-emitting pixel driving circuit, comprising an initialization stage, a threshold detection stage, and a pixel light-emitting stage, wherein:
in the initialization stage, under control of a first scanning signal line, a first transistor is configured to transmit an initialization voltage to an anode of a light-emitting element, and a second transistor is configured to transmit the initialization signal to a gate electrode of a driving transistor, such that the light-emitting element and the driving transistor fulfill initialization,
in the threshold detection stage, a third transistor is configured to transmit a data signal voltage to a first electrode of the driving transistor under control of a second scanning signal line, thereby fulfilling threshold detection of the driving transistor, and
in the pixel light-emitting stage, a fourth transistor is configured to transmit a first power supply voltage signal to the driving transistor under control of a first light-emitting control signal line, and a fifth transistor is configured to control electric connection between a second electrode of the driving transistor and the anode of the light-emitting element under control of a second light-emitting control signal line, such that the driving transistor drives the light-emitting element to emit light.

12. The driving method according to claim 11, wherein:
the initialization voltage is a voltage signal transmitted by the first scanning signal line.

13. The driving method according to claim 12, wherein:
the first light-emitting control signal line is configured to output a first control signal, and the second light-emitting control signal line is configured to output a second control signal; or
the first light-emitting control signal line is multiplexed as the second light-emitting control signal line to output the first control signal.

14. The driving method according to claim 13, further comprising a voltage level holding stage, wherein:
a signal carried by the first scanning signal line is delayed for a preset period of time with respect to a signal carried by the second scanning signal line; and
in the voltage level holding stage, the fourth transistor and the fifth transistor are turned off under control of the first control signal, the first transistor and the second transistor are turned off under control of the first scanning signal line, the third transistor is turned on under control of the second scanning signal line, and a voltage level of the gate electrode of the driving transistor and a voltage level of the anode of the light-emitting element remain substantially unchanged.

15. The driving method according to claim 11, further comprising:
an initialization signal line, wherein the initialization voltage is a voltage signal transmitted by the initialization signal line.

16. An organic light-emitting display panel, comprising a plurality of rows of pixel units, wherein each row of pixel units includes a plurality of organic light-emitting pixel driving circuits, and an organic light-emitting pixel driving circuit includes:
a light-emitting element;
a driving transistor, configured to drive the light-emitting element to emit light;
a first transistor, configured to transmit an initialization voltage to the light-emitting element;
a second transistor, configured to transmit the initialization voltage to the driving transistor and compensate a threshold voltage of the driving transistor;
a third transistor, configured to transmit a data signal voltage to the driving transistor;
a fourth transistor, configured to transmit a first power supply voltage signal to the driving transistor;
a fifth transistor, configured to control an electric connection between the driving transistor and an anode of the light-emitting element; and
a capacitor, configured to store the data signal voltage transmitted to the driving transistor.

17. The organic light-emitting display panel according to claim 16, wherein:
the first transistor and the second transistor are under control of a first scanning signal line;
the third transistor is under control of a second scanning signal line;
the fourth transistor is under control of a first light-emitting control signal line; and
the fifth transistor is under control of a second light-emitting control signal line and is coupled between the driving transistor and the anode of the light-emitting element.

18. The organic light-emitting display panel according to claim 17, wherein:
a row of pixel units is connected to one first scanning signal line and one second scanning signal line.

19. The organic light-emitting display panel according to claim 18, wherein;
a second scanning signal line connected to an i^{th} row of pixel units is multiplexed as a first scanning signal line connected to an (i+1)^{th} row of pixel units, where i is a positive integer.
